(19) United States
(12) Patent Application Publication
(10) Pub. No.: US 2015/0044783 A1
(43) Pub. Date: Feb. 12, 2015

(54) METHODS OF ALLEVIATING ADVERSE STRESS EFFECTS ON A WAFER, AND METHODS OF FORMING A SEMICONDUCTOR DEVICE

(71) Applicant: Micron Technology, Inc., Boise, ID (US)

(72) Inventor: Andrew Dennis Watson Carswell, Boise, ID (US)

(73) Assignee: Micron Technology, Inc., Boise, ID (US)

(21) Appl. No.: 13/964,544

(22) Filed: Aug. 12, 2013

(51) Int. Cl. H01L 21/306; H01L 21/66

(52) U.S. Cl. CPC H01L 21/30625; H01L 22/20
USPC 438/5; 438/692

(57) ABSTRACT

A method of forming a forming a semiconductor device comprises forming at least one semiconductor device structure over a surface of a wafer. An opposing surface of the wafer is subjected to at least one chemical-mechanical polishing process to form a modified opposing surface of the wafer comprising at least one recessed region and at least one elevated region. Additional methods of forming a semiconductor device, and methods of reducing stress on a wafer are also described.

### TECHNICAL FIELD

Embodiments of the disclosure relate generally to the field of semiconductor device design and fabrication. More specifically, the disclosure, in various embodiments, relates to methods of alleviating adverse stress effects on a wafer, and to methods of forming a semiconductor device.

### BACKGROUND

During the formation of semiconductor devices (e.g., dynamic random access memories, static random access memories, microprocessors, logic) various materials (e.g., dielectric materials, conductive materials, semiconductive materials) are provided on or over a surface (e.g., at least an active surface) of an undivided wafer and processed (e.g., patterned, doped, etched, annealed), and portions of these materials as well as portions of the wafer itself are selectively removed. After forming the semiconductor devices, the undivided wafer is divided (e.g., singulated), a lead frame for each of the semiconductor devices is assembled, and the operations and functions of the semiconductor devices produced are inspected.

Disadvantageously, the processes used to form the semiconductor devices, as well as the structural geometries of the semiconductor devices themselves, can produce stress patterns on the wafer effectuating out-of-plane deformation of the wafer. For example, the various deposition, patterning, doping, etching, and annealing processes utilized to form different components of a semiconductor device can produce a distribution of residual mechanical stresses (e.g., compressive stresses, tensile stresses) on the wafer that can result in undesired curvature (i.e., warping, bowing, dishing, bending) of the wafer. The curvature can be concave (e.g., in the presence of compressive stresses), convex (e.g., in the presence of tensile stresses), or a combination thereof.

FIG. 1A illustrates a top-down view of a wafer 100 exhibiting stress-induced curvature. The overall curvature of the wafer 100 can be defined using the following equation:

Overall Curvature²=Radial Curvature²+Residual Curvature² (1),

wherein the radial curvature of the wafer 100 is depicted in FIG. 1B, and wherein the residual curvature of the wafer 100 is depicted in FIG. 1C. The residual (i.e., non-radial) curvature of the wafer 100 can be defined using the following equation:

Residual Curvature²=Dipole Curvature²+Quadrupole Curvature² (2),

wherein the dipole curvature of the wafer 100 is depicted in FIG. 1D, and wherein the quadrupole curvature of the wafer 100 is depicted in FIG. 1E.

A wafer exhibiting out-of-plane deformation (e.g., curvature) can be difficult to process and can result in defects in and damage to the semiconductor devices formed thereon. For example, a warped wafer may induce focus variations that may interfere with, if not preclude, proper registration of a desired photolithography pattern during the formation of a semiconductor device and induce out-of-tolerance critical dimension variations. Such interference can negatively affect the manufacture, performance, and/or reliability of the semiconductor device. In addition, a warped wafer may be difficult to process, handle, and/or transport, and may even break during processing, handling, and/or transportation. For example, manipulation of a wafer is generally performed using a flexible chuck to hold the wafer through application of a vacuum to one side thereof, and it can be difficult to obtain and/or maintain an airtight seal between a warped wafer and the flexible chuck. Failing to obtain and/or maintain the airtight seal may result in attachment problems and/or can cause the semiconductor wafer to dislodge from the flexible chuck and become damaged upon contact with another surface. Furthermore, a warped wafer may be difficult to singulate into individual dice, each including a semiconductor device integrated circuit, as the diamond saw conventionally used for singulation may not sever the wafer completely.

Examples of methods commonly utilized to counteract stresses on a wafer (i.e., and, hence, reduce wafer curvature) include depositing at least one layer of material on a backside (e.g., non-active side) of the wafer prior to forming semiconductor device structures on or over a front side (e.g., active side, device side) of the wafer, completely removing one or more material(s) on the backside of the wafer, and uniformly removing portions of one or more material(s) on the backside of the wafer through various processes (e.g., etching). Unfortunately, however, while such methods can alleviate some of the stresses associated with wafer curvature, they can provide limited degrees of freedom, can be inadequate to alleviate other stresses, and/or can require complex and costly multi-step operations.

It would, therefore, be desirable to have improved methods of relieving stresses on a wafer during and/or after the formation of semiconductor devices thereon or thereover. It would be further desirable if such methods could be tailored to at least one process (e.g., at least one of a deposition process, a patterning process, a doping process, an etching process, and an annealing process) utilized to form the semiconductor devices so as to substantially counteract at least one distribution of residual stresses on the wafer resulting from the at least one process.

### BRIEF DESCRIPTION OF THE SEVERAL VIEWS OF THE DRAWINGS

FIG. 1A is a top elevational image illustrating an overall residual out-of-plane curvature of a wafer exhibiting stress-induced curvature;

FIG. 1B is a top elevational schematic image illustrating a radial curvature component of the overall out-of-plane curvature of the wafer shown in FIG. 1A;

FIG. 1C is a top elevational schematic image illustrating a residual curvature component of the overall out-of-plane curvature of the wafer shown in FIG. 1A;

FIG. 1D is a top elevational schematic image illustrating a dipole curvature component of the overall out-of-plane curvature of the wafer shown in FIG. 1A;

FIG. 1E is a top elevational schematic image illustrating a quadrupole curvature component of the overall out-of-plane curvature of the wafer shown in FIG. 1A;

FIGS. 2A through 4B are perspective (i.e., FIGS. 2A, 3A, and 4A) and partial cross-sectional (i.e., FIGS. 2B, 3B, and 4B) views of a wafer assembly and illustrate a method of alleviating adverse stress effects on a wafer in accordance with embodiments of the disclosure; and

FIGS. 5A and 5B are perspective (i.e., FIG. 5A) and partial cross-sectional (i.e., FIG. 5B) views of a wafer assembly and illustrate another method alleviating adverse stress effects on a wafer, in accordance with additional embodiments of the disclosure.

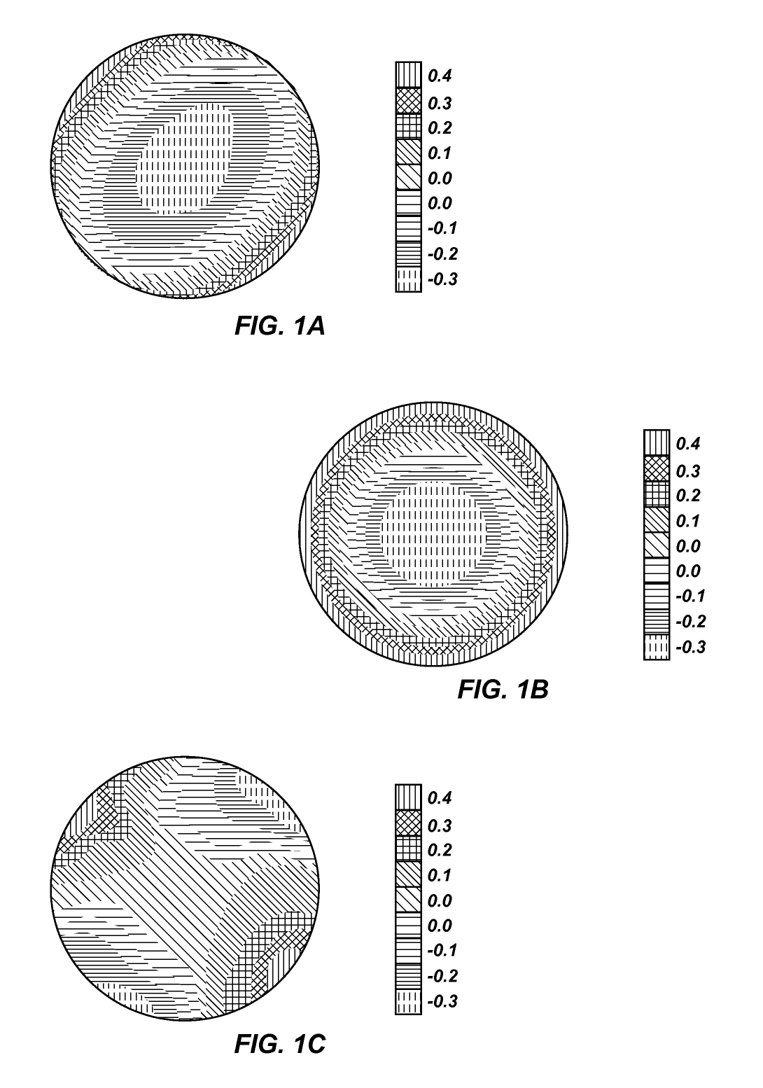

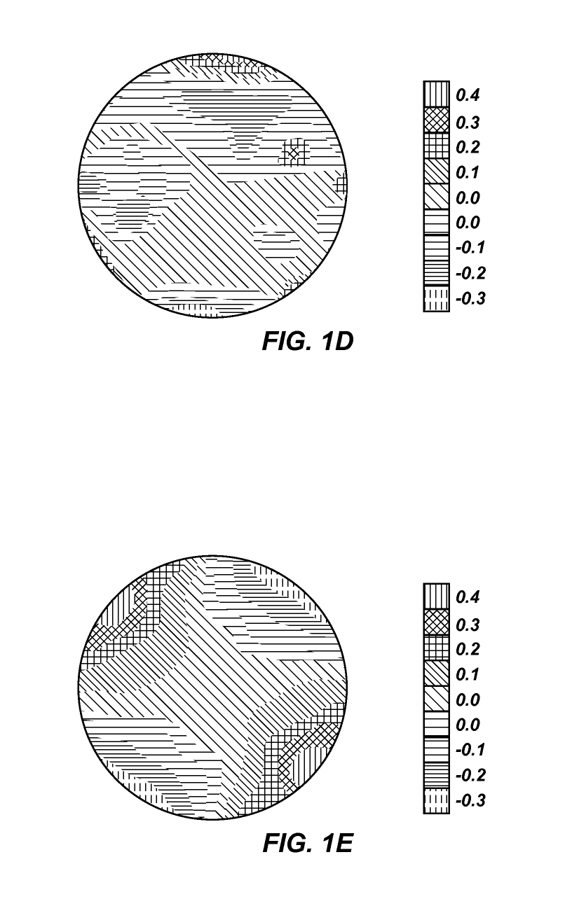

### DETAILED DESCRIPTION

Methods of alleviating adverse stress effects on a wafer are described, as are methods of forming semiconductor devices. In some embodiments, a method of alleviating adverse stress effects on a wafer includes subjecting a surface of the wafer to at least one chemical-mechanical polishing (CMP) process to remove predetermined portions of the wafer after performing at least one process to form one or more semiconductor device structures on or over an opposing surface of the wafer. As used herein, the term “CMP process” includes processes employing mechanical abrasion alone, as well as CMP processes employing at least one chemically reactive material formulated to remove material of the wafer. The CMP process may be tailored to produce stresses that counteract other stresses imposed on the wafer by the formation of the semiconductor device structure. Accordingly, the CMP process may significantly reduce, if not eliminate, out-of-plane curvature of the wafer resulting from the formation of the semiconductor device structures. Following the CMP process, at least one additional process may be performed to produce one or more semiconductor devices including the one or more semiconductor device structures. At least one additional CMP process may be utilized before and/or after the additional process to remove other predetermined portions of the wafer. The additional CMP process may be tailored to produce additional stresses that counteract other stresses imposed on the wafer through the additional process. Thus, the additional CMP process may reduce, if not eliminate, out-of-plane deformation (e.g., curvature) of the wafer resulting from the additional process. The methods of the disclosure may increase production efficiency, increase wafer yield, reduce manufacturing costs, and reduce defects in and damage to the produced semiconductor devices (i.e., increasing semiconductor performance and reliability) as compared to many conventional methods of forming semiconductor devices.

The following description provides specific details, such as material types, material thicknesses, and processing conditions in order to provide a thorough description of embodiments of the disclosure. However, a person of ordinary skill in the art will understand that the embodiments of the disclosure may be practiced without employing these specific details. Indeed, the embodiments of the disclosure may be practiced in conjunction with conventional fabrication techniques employed in the industry. In addition, the description provided below does not form a complete process flow for manufacturing a semiconductor device. The semiconductor device structures and wafer assemblies described below do not form a complete semiconductor device. Only those process acts and structures necessary to understand the embodiments of the disclosure are described in detail below. Additional acts to form the complete semiconductor device from semiconductor device structures and wafer assemblies may be performed by conventional fabrication techniques. Also note, any drawings accompanying the present application are for illustrative purposes only, and are thus not drawn to scale. Additionally, elements common between figures may retain the same numerical designation.

As used herein, the singular forms “a,” “an,” and “the” are intended to include the plural forms as well, unless the context clearly indicates otherwise.

As used herein, the term “and/or” includes any and all combinations of one or more of the associated listed items.

As used herein, relational terms, such as “first,” “second,” “top,” “bottom,” “upper,” “lower,” “over,” “under,” etc., are used for clarity and convenience in understanding the disclosure and accompanying drawings and does not connote or depend on any specific preference, orientation, or order, except where the context clearly indicates otherwise.

As used herein, the term “substantially,” in reference to a given parameter, property, or condition, means to a degree that one skilled in the art would understand that the given parameter, property, or condition is met with a small degree of variance, such as within acceptable manufacturing tolerances.

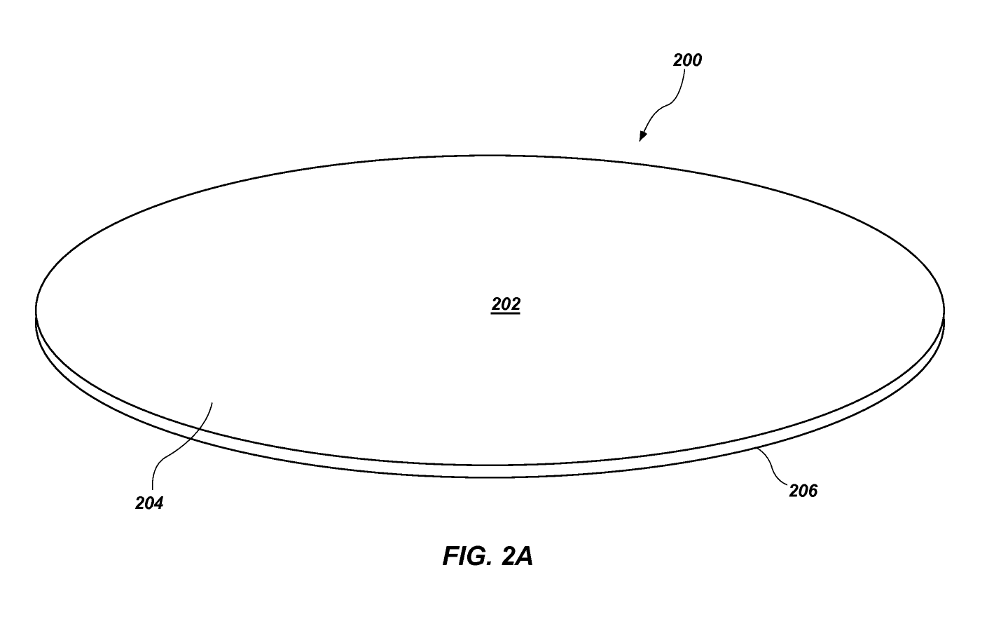

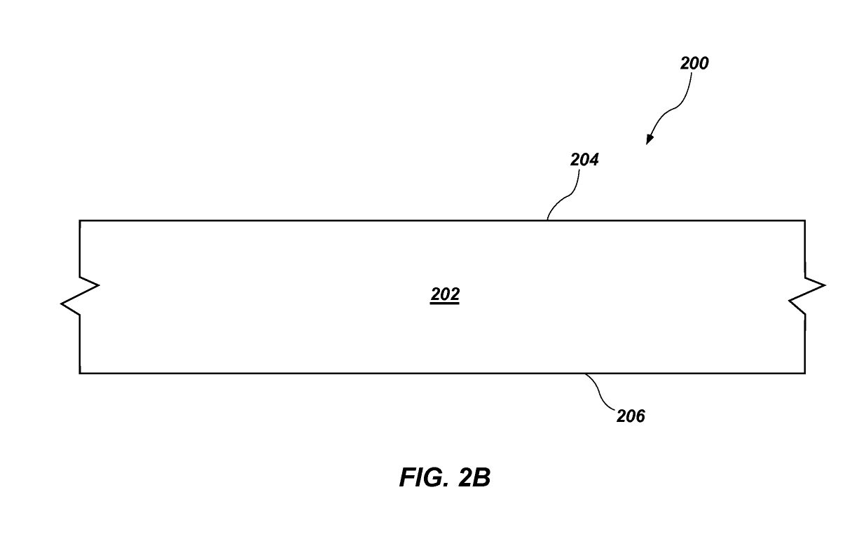

FIGS. 2A through 4B, are simplified perspective (i.e., FIGS. 2A, 3A, and 4A) and partial cross-sectional views (i.e., FIGS. 2B, 3B, and 4B) illustrating embodiments of a method of alleviating adverse stress effects, such as result from non-radial, residual stress, on a wafer during and/or after the fabrication of semiconductor devices thereon. With the description as provided below, it will be readily apparent to one of ordinary skill in the art that the methods described herein may be used in various applications. In other words, the methods of the disclosure may be used whenever it is desired to alleviate adverse stress effects on a wafer resulting from the formation of semiconductor device component structures thereon or thereover.

FIG. 2A illustrates simplified perspective view of a wafer assembly 200 including a wafer 202 in accordance with an embodiment of the disclosure. The wafer 202 may include a surface 204 (also referred to as a “front side” surface, which may also be characterized as an “active” surface), and an opposing surface 206 (also referred to as a “backside” surface). As used herein, the terms “wafer” and “substrate” mean and include a base material or construction upon which additional materials are formed. The wafer 202 may be a semiconductor wafer. The wafer 202 may be a conventional silicon wafer, or other bulk wafer comprising a layer of semiconductive material. As used herein, the term “bulk wafer” means and includes not only silicon wafers, but also silicon-on-insulator (SOI) wafers, such as silicon-on-sapphire (SOS) wafers, and silicon-on-glass (SOG) wafers, epitaxial layers of silicon on a base semiconductor foundation, and other semiconductor or optoelectronic materials, such as silicon-germanium, germanium, gallium arsenide, gallium nitride, and indium phosphide. FIG. 2B illustrates a partial cross-sectional view of the wafer assembly 200 at the processing stage depicted in FIG. 2A.

As shown in FIGS. 2A and 2B, the wafer 202 may be substantially planar. In further embodiments, the wafer 202 may be at least partially non-planar (e.g., curved, warped, bowed, dished, bent). In addition, as depicted in FIG. 2A, the wafer 202 may exhibit a generally circular peripheral shape. In additional embodiments, the wafer 202 have a different peripheral shape, such as a tetragonal (e.g., square, rectangular, etc.) shape. The wafer 202 may have any desired dimensions (e.g., diameter, length, width, thickness), at least partially depending on at least one of a desired configuration (e.g., size, shape, etc.) and a desired quantity of semiconductor devices to be formed thereon or thereover, as described in further detail below.

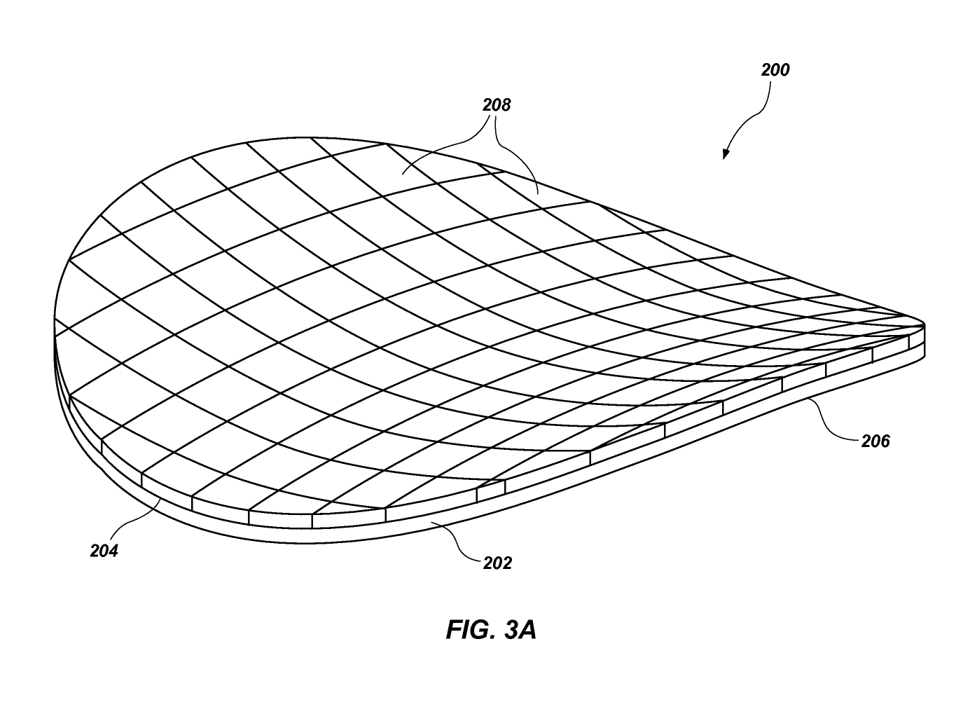

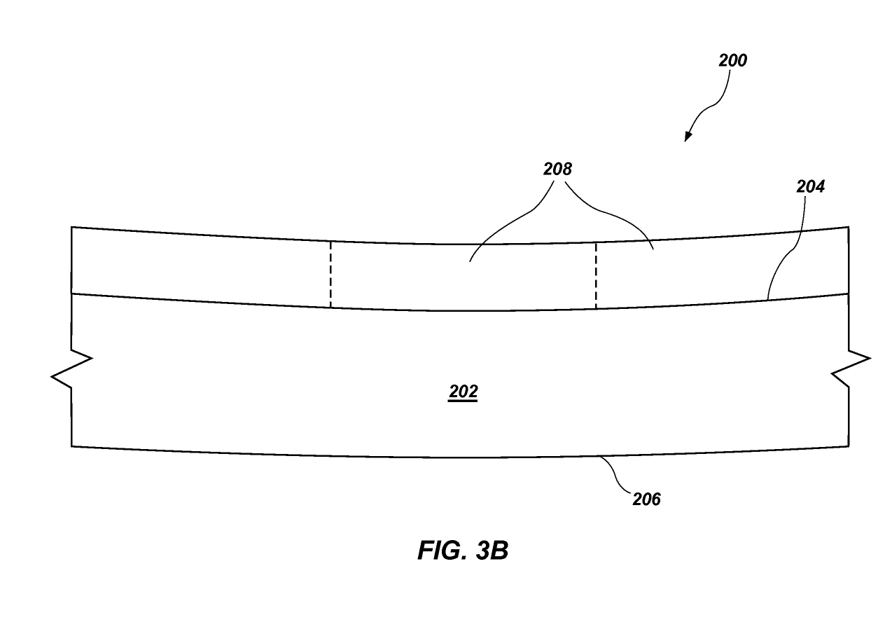

Referring to FIG. 3A, semiconductor device structures 208 in the form of integrated circuitry may be formed on or over the active surface 204 of the wafer 202. The semiconductor device structures 208 may be integrated circuit structures to be included in a like number of semiconductor devices to be formed on or over the wafer 202, as described in further detail below. The semiconductor device structures 208 may, for example, be formed of and include at least one of a dielectric material (e.g., silicon dioxide, silicon oxynitride, silicon nitride, another dielectric oxide material, a dielectric polymer material), a conductive material (e.g., a metal, a metal alloy, a conductive oxide material, a conductive polymer material), and a semiconductive material (e.g., silicon-germanium, germanium, gallium arsenide, gallium nitride, indium phosphide). The semiconductor device structures 208 may have any desired shape, size, and number of layers. FIG. 3B illustrates, schematically, a partial cross-sectional view of the wafer assembly 200 at the processing stage depicted in FIG. 3A.

The semiconductor device structures 208 may be formed on or over the surface 204 of the wafer 202 using conventional processes and equipment, which are not described in detail herein. By way of non-limiting example, the semiconductor device structures 208 may be formed on the surface 204 of the wafer 202 by forming at least one material on or over the wafer 202 (e.g., through a conventional process, such as physical vapor deposition, chemical vapor deposition, or atomic layer deposition), forming a photoresist material on or over the material, selectively photoexposing (e.g., using at least one of a mask and direct writing) and developing the photoresist material to form a patterned photoresist material, etching (e.g., at least one of wet etching and dry etching) the material using the patterned photoresist material, and removing remaining photoresist material (e.g., using at least one of wet etching, dry etching, and chemical-mechanical polishing).

As shown in FIGS. 3A and 3B, the formation of the semiconductor device structures 208 on or over the surface 204 of the wafer 202 may impose one or more stresses (e.g., residual stresses) on the wafer 202 that may induce an out-of-plane deformation in one or more regions of the wafer 202. For example, the wafer 202 may become at least partially curved (e.g., warped, bowed, dished, bent). Greater magnitudes of stress may result in greater curvature of the wafer 202. In additional embodiments, the stresses on the wafer 202 may be insufficient to curve the wafer 202, but may otherwise contribute to future curving of the wafer 202 if combined with one or more other stresses produced from additional processing acts to form a semiconductor device on or over the wafer 202, as described in further detail below. A distribution of the stresses on the wafer 202 may or may not correspond to a pattern and configuration of the semiconductor device structures 208 on the wafer 202.

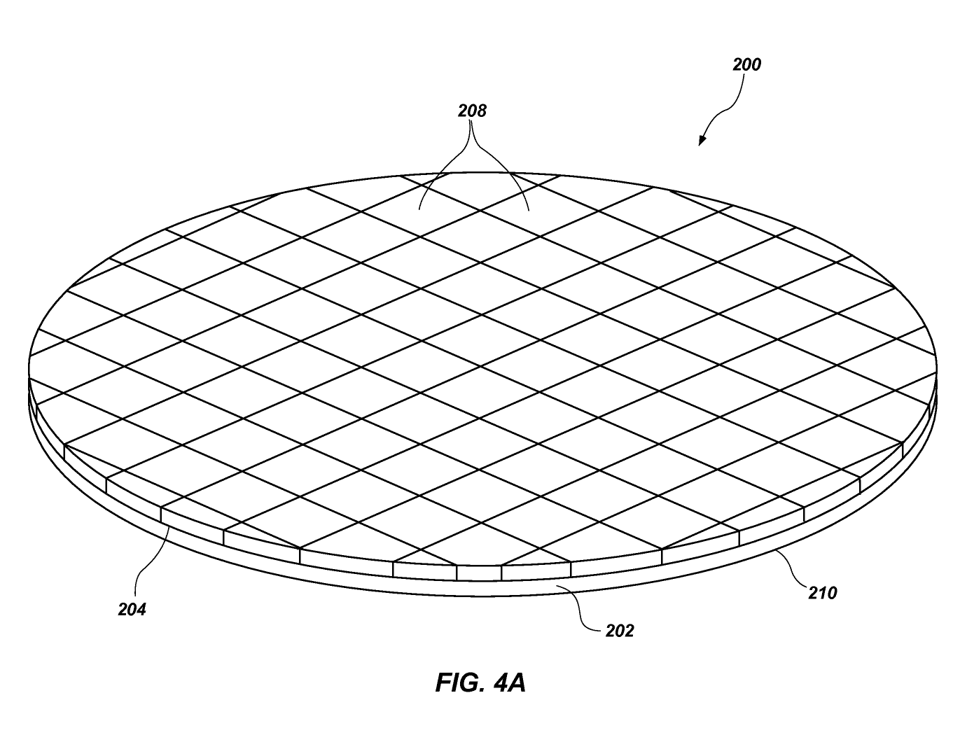

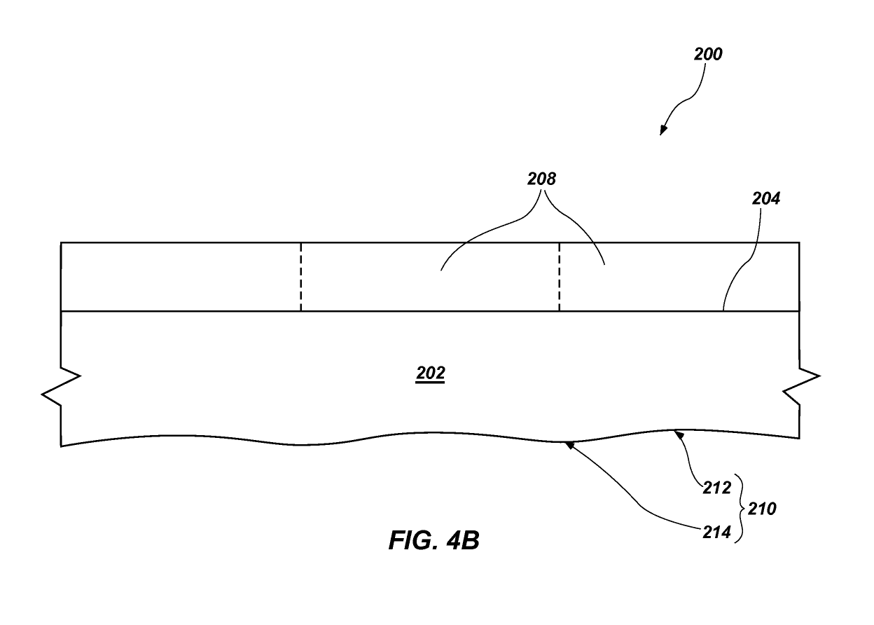

Referring to FIG. 4A, following the formation of the semiconductor device structures 208 on or over the surface 204 of the wafer 202, the opposing surface 206 (FIGS. 3A and 3B) of the wafer 202 may be subjected to at least one CMP process to form a modified opposing surface 210. As shown in FIG. 4B, which illustrates a partial cross-sectional view of the wafer assembly 200 at the processing stage depicted in FIG. 4A, the CMP process may remove one or more portion(s) of the wafer 202 such that modified opposing surface 210 includes at least one recessed region 212 and at least one elevated region 214.

The CMP process may employ a CMP device or apparatus configured with a wafer contacting member, such as a polishing pad, mounted, orientable and operably coupled to a drive apparatus to enable the CMP device to remove material from at least one portion of the wafer 202 without removing at least one other portion of the wafer 202. For example, the CMP process may utilize a CMP apparatus including at least one rotational surface configured (e.g., sized, and shaped) and operable (e.g., postionable, orientable, rotatable, and applicable toward the opposing surface 206 of the wafer 202) to remove less than a lateral entirety and/or less than a longitudinal entirety of the wafer 202. The CMP process may include contacting one or more regions of the opposing surface 206 (FIGS. 3A and 3B) of the wafer 202 with at least one rotating polishing pad operatively associated with the at least one rotational surface of the CMP device in the presence of at least one polishing slurry between the polishing pad and the opposing surface 206. The polishing pad and the polishing slurry may be selected based on the material characteristics and desired post-polish configuration of the wafer 202. The polishing slurry may, for example, include abrasive particles and, optionally, at least one chemically reactive material formulated to remove the material of the wafer 202 at a desired rate.

The CMP process may be tailored to alleviate the stresses imposed on the wafer 202 by the formation of the semiconductor device structures 208. Each recessed region 212 formed using the CMP process may have a location, size (e.g., width, depth), and shape facilitating a selective reduction or increase in the stresses on the wafer 202. For example, each recessed region 212 (and, hence, each elevated region 214) of the modified opposing surface 210 of the wafer 202 may be located, sized, and shaped to counteract or alleviate a distribution or pattern of residual stresses (e.g., a pattern of at least one of tensile stresses and compressive stresses) on the wafer 202 produced by the formation of the semiconductor device structures 208. Accordingly, in embodiments where the formation of the semiconductor device structures 208 results in out-of-plane deformation (e.g., convex curvature, concave curvature, or a combination thereof) of the wafer 202, the CMP process may be used to reduce the out-of-plane deformation of the wafer 202. The CMP process may, for example, return the wafer 202 to a substantially non-curved (e.g., substantially planar) configuration. In some embodiments, the CMP process may substantially reduce, if not eliminate, residual curvature (e.g., at least one of dipole curvature and quadrupole curvature) of the wafer 202. In additional embodiments, the CMP process may enable the wafer 202 to maintain a substantially planar (e.g., substantially non-curved) configuration during and/or after additional processing to form a semiconductor device thereon, as described in further detail below.

To determine the desired location, size, and shape for each recessed region 212 of the modified opposing surface 210 of the wafer 202, the stresses on the wafer 202 may be determined (e.g., measured). A distribution of stresses on the wafer 202 may, for example, be determined using conventional optical techniques, which are not described in detail herein. After determining the stresses on the wafer 202 (or relying upon previous stress data obtained following similar processing), the CMP process may be used to selectively form the recessed regions 212 within the wafer 202 to produce additional stresses that at least partially compensate for the aforementioned stresses on the wafer 202. For example, the CMP process may be used to form or amplify at least one stress orientation (e.g., compressive, and/or tensile) on the wafer 202 that counteracts at least one other stress orientation (e.g., compressive, and/or tensile) imposed on the wafer 202 through the formation of the semiconductor device structures 208. The CMP process (and, hence, the location, size, and shape of each recessed region 212) may also be employed to account for stresses anticipated to be imposed on the wafer 202 during subsequent processing acts.

As depicted in FIG. 4B, the at least one recessed region 212 of the modified opposing surface 210 may comprise multiple recessed regions 212. The recessed regions 212 may be symmetrically distributed across the modified opposing surface 210, or may be asymmetrically distributed across the modified opposing surface 210. In addition, each of the recessed regions 212 may have substantially the same size and shape, or at least one of the recessed regions 212 may have at least one of a different size and a different shape than at least one other of the recessed regions 212. Each of the recessed regions 212 may independently have a depth that does not substantially interfere with additional processing, handling, and/or transportation of the wafer assembly 200. In some embodiments, each of the recessed regions 212 may independently have a depth within a range of from about 10 Angstroms (Å) to about 2000 Å. A transition between each of the recessed regions 212 and the elevated regions 214 adjacent thereto may be smooth and gradual. The symmetry, size, and shape of each of the recessed regions 212 (and, hence, each of the elevated regions 214) may at least partially depend on the symmetry, size, and shape of each of the semiconductor device structures 208 formed on or over the surface 204 of the wafer 202.

In embodiments wherein multiple recessed regions 212 are formed using the CMP process, each of the recessed regions 212 may be formed using substantially similar process parameters (e.g., substantially similar polishing slurries, polishing pads, polishing pad speeds, polishing downforces, polishing durations), or at least one of the recessed regions 212 in the wafer may be formed using at least one different process parameter (e.g., a different polishing slurry, polishing pad, polishing pad speed, polishing pad downforce, and/or polish duration) than at least one other of the recessed regions 212. In some embodiments, substantially similar process parameters are used to form each of the recessed regions 212 of the modified opposing surface 210 of the wafer 202.

Thus, in accordance with embodiments of the disclosure, a method of forming a semiconductor device comprises forming at least one semiconductor device structure over a surface of a wafer. An opposing surface of the wafer is subjected to at least one chemical-mechanical polishing process to form a modified opposing surface of the wafer comprising at least one recessed region and at least one elevated region.

Furthermore, in accordance with additional embodiments of the disclosure, a method of alleviating adverse effects of stress on a wafer comprises forming recesses in a surface of the wafer to produce at least one stress on the wafer of at least one of a type, a direction, and a magnitude of opposite type than that of at least one other stress imposed on the wafer resulting from the formation of a semiconductor device structure over another surface of the wafer.

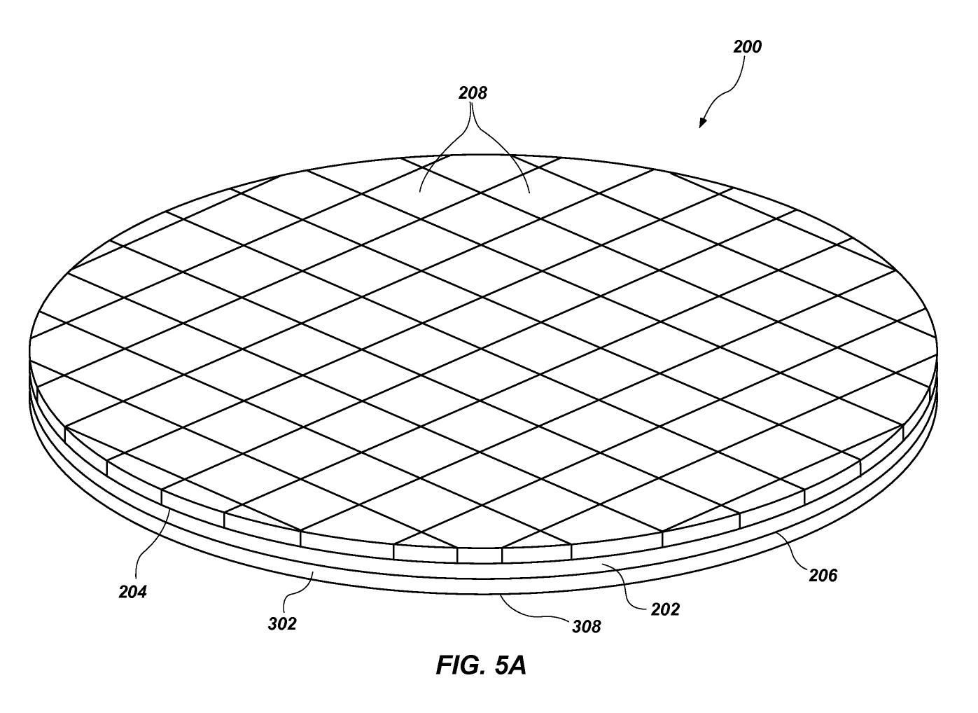

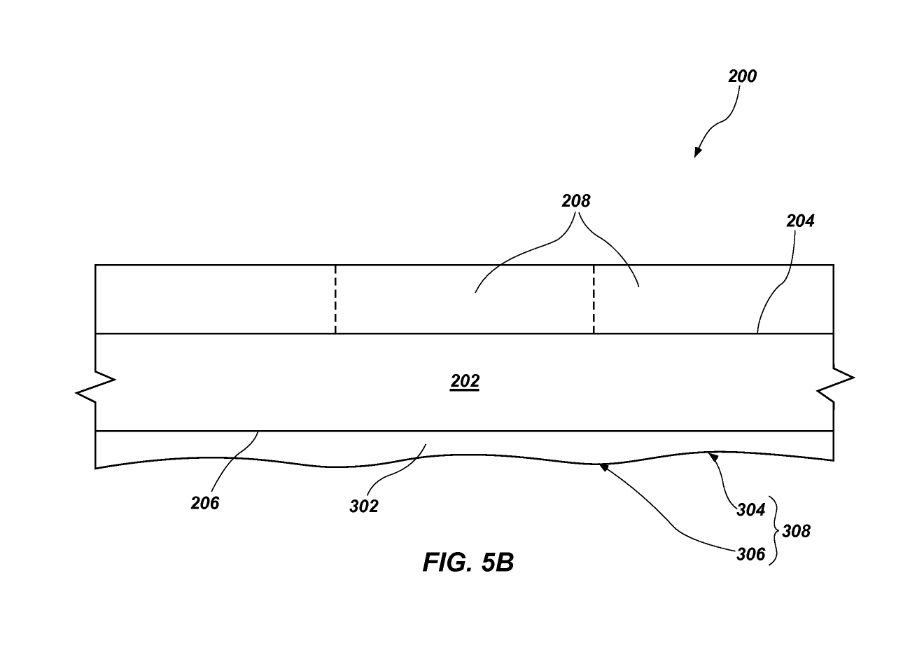

Referring to FIG. 5A, in additional embodiments, at least one material 302 may be formed on the opposing surface 206 of the wafer 202 and subjected to a CMP process to alleviate adverse stress effects on the wafer 202 produced through the formation of the semiconductor device structures 208. The at least one material 302 may be formed on the opposing surface 206 of the wafer 202 before, during, and/or after the formation of the semiconductor device structures 208 on the surface 204 of the wafer 202. FIG. 5B illustrates a partial cross-sectional view of the wafer assembly 200 at the processing stage depicted in FIG. 5A.

The at least one material 302 may be formed of and include any material able to reduce or balance stresses (e.g., residual stresses, such as at least one of tensile stresses and compressive stresses) on the wafer 202. For example, the at least one material 302 may comprise at least one of a dielectric material, a conductive material, and a semiconductive material. In some embodiments, the at least one material 302 is formed of and includes a single material (e.g., a single dielectric material, a single conductive material, or a single semiconductive material). In addition embodiments, the at least one material 302 is formed of and includes multiple materials. For example, the at least one material 302 may comprise a material stack including at least two films including mutually different materials. If the at least one material 302 is formed of and includes a material stack, at least one of the films may be formulated as a stop layer for a subsequent CMP process.

After forming the semiconductor device structures 208 on or over the surface 204 of the wafer 202, an exposed surface of the at least one material 302 may be subjected to at least one CMP process, in a manner substantially similar to that previously described in relation to FIGS. 4A and 4B for the formation of the modified opposing surface 210 of the wafer 202, to form a modified exposed surface 308 of the material 302. As shown in FIG. 5B, the modified exposed surface 308 may include at least one recessed region 304 and at least one elevated region 306. The material 302 and the CMP process performed thereto may be used to form or amplify at least one stress orientation (e.g., compressive, and/or tensile) on the wafer 202 that counteracts at least one other stress orientation (e.g., compressive, and/or tensile) imposed on the wafer 202 through the formation of the semiconductor device structures 208.

Thus, in accordance with additional embodiments of the disclosure, a method of forming a semiconductor device comprises forming at least one semiconductor device structure over a first surface of a wafer. At least one material is formed over a second, opposite surface of the wafer. The at least one material is subjected to at least one chemical-mechanical polishing process to remove at least one portion of the material relative to at least one other portion of the material.

With returned reference to FIGS. 4A and 4B, after using the CMP process to reduce the stresses imposed on the wafer 202 through the formation the semiconductor device structures 208, the semiconductor device structures 208 may be subjected to additional processing. By way of non-limiting example, at least one additional material may be formed on, over, or within each of the semiconductor device structures 208 using conventional processes (e.g., deposition, doping, photo-patterning, etching, and/or annealing processes). The additional material may include any material (e.g., a dielectric material, a conductive material, a semiconductive material) to be included in a semiconductor device including the semiconductor device structure 208 and the additional material. Thereafter, the modified opposing surface 210 of the wafer 202 (FIG. 4B) (or the modified exposed surface 308 of the material 302 shown in FIG. 5B) may be subjected to at least one additional CMP process to alleviate adverse effects of additional stresses on the wafer 202. The additional CMP process may be tailored to alleviate the stresses imposed on the wafer 202 through the formation of the additional material, and may be used remove one or more additional portion(s) of the wafer 202 in a manner substantially similar to that previously described with respect to FIGS. 4A and 4B for the formation of the modified opposing surface 210 of the wafer 202.

If the at least one additional material includes multiple additional materials, the additional CMP process may be performed after forming and, optionally selectively removing a portion or portions of a first additional material on, over, or within each of the semiconductor device structures 208 and prior to forming a second additional material on, over, or within each of the semiconductor device structures 208, or after all additional material processing has occurred.

The methods of the disclosure may advantageously facilitate a reduction in the adverse effects of stresses (e.g., residual stresses) on a wafer 202 following the formation of semiconductor device structures 208 and/or semiconductor devices on or over a surface 204 of the wafer 202. The reduction in the adverse stress effects may reduce, if not eliminate, out-of-plane deformation (e.g., residual curvature) of the wafer 202 resulting from the formation of the semiconductor device structures 208 and/or the semiconductor devices. The reduction in out-of-plane deformation may increase the simplicity of additional processing acts (e.g., deposition acts, photo-patterning acts, etching acts, singulation acts), and may reduce stress-imposed damage to and defects in the resulting semiconductor device structures 208 and/or semiconductor devices as compared to many conventional semiconductor device fabrication processes. Accordingly, the methods of the disclosure may reduce production costs, improve production efficiency, and improve the performance and reliability of produced semiconductor devices as compared to many conventional semiconductor device fabrication processes. In addition, the stress-reduction processes (e.g., CMP processes) of the disclosure may provide greater degrees of freedom, and may be better tailored to particular stress distributions resulting from the formation of the semiconductor device structures 208 and/or semiconductor devices as compared to many conventional methods of reducing stress on a wafer.

While the disclosure is susceptible to various modifications and alternative forms, specific embodiments have been shown by way of example in the drawings and have been described in detail herein. However, the disclosure is not intended to be limited to the particular forms disclosed. Rather, the disclosure is to cover all modifications, equivalents, and alternatives falling within the scope of the disclosure as defined by the following appended claims and their legal equivalents.

What is claimed is:

1. A method of forming a semiconductor device, comprising:
forming at least one semiconductor device structure over a surface of a wafer; and
subjecting an opposing surface of the wafer to at least one chemical-mechanical polishing process to form a modified opposing surface of the wafer comprising at least one recessed region and at least one elevated region.

2. The method of claim 1, wherein forming at least one semiconductor device structure on a surface of a wafer comprises subjecting the surface of the wafer to at least one of a material deposition process, a material removal process, a doping process, and an annealing process.

3. The method of claim 1, wherein subjecting an opposing surface of the wafer to at least one chemical-mechanical polishing process comprises subjecting the opposing surface of the wafer to the at least one chemical-mechanical polishing process after forming the at least one semiconductor device structure on the surface of the wafer.

4. The method of claim 1, wherein subjecting an opposing surface of the wafer to at least one chemical-mechanical polishing process to form a modified opposing surface of the wafer comprises forming the modified opposing surface to comprise multiple recessed regions.

5. The method of claim 1, wherein subjecting an opposing surface of the wafer to at least one chemical-mechanical polishing process comprises removing portions of the wafer to alleviate adverse effects of stresses on the wafer resulting from forming the at least one semiconductor device structure over the surface of the wafer.

6. The method of claim 5, wherein removing portions of the wafer to alleviate adverse effects of stresses on the wafer comprises selectively removing portions of material of the wafer relative to other portions of the wafer to counteract a distribution of the stresses on the wafer.

7. The method of claim 1, wherein subjecting an opposing surface of the wafer to at least one chemical-mechanical polishing process comprises substantially reducing a residual curvature of the wafer using the at least one chemical-mechanical polishing process.

8. The method of claim 1, further comprising forming at least one additional material over the at least one semiconductor device structure after subjecting the opposing surface of the wafer to the at least one chemical-mechanical polishing process.

9. The method of claim 8, further comprising subjecting the at least one additional material to at least one of a doping process, a material removal process, and an annealing process.

10. The method of claim 8, further comprising subjecting the modified opposing surface of the wafer to at least one additional chemical-mechanical polishing process after forming the at least one additional material over the at least one semiconductor device structure.

11. The method of claim 1, wherein subjecting an opposing surface of the wafer to at least one chemical-mechanical polishing process to form a modified opposing surface comprising at least one recessed region and at least one elevated region comprises forming the modified opposing surface to have a substantially symmetric distribution of recessed regions.

12. The method of claim 1, wherein subjecting an opposing surface of the wafer to at least one chemical-mechanical polishing process to form a modified opposing surface comprising at least one recessed region and at least one elevated region comprises forming the modified opposing surface to have a substantially asymmetric distribution of recessed regions.

13. The method of claim 1, further comprising determining a pattern of the stresses on the wafer after forming the at least one semiconductor device structure on the surface of the wafer.

14. The method of claim 13, wherein subjecting an opposing surface of the wafer to at least one chemical-mechanical polishing process comprises forming the at least one recessed region of the modified opposing surface to counteract the pattern of the stresses on the wafer.

15. A method of forming a semiconductor device, comprising:
forming at least one semiconductor device structure over a first surface of a wafer;
forming at least one material over a second, opposite surface of the wafer; and
subjecting the at least one material to at least one chemical-mechanical polishing process to remove at least one portion of the material relative to at least one other portion of the material.

16. The method of claim 15, wherein subjecting the at least one material to at least one chemical-mechanical polishing process comprises forming recessed regions on an exposed surface of the at least one material to produce other stress on the wafer that counteracts stress on the wafer.

17. The method of claim 15, wherein forming at least one material over a second, opposite surface of the wafer comprises forming multiple materials over the second, opposite surface of the wafer.

18. The method of claim 15, further comprising measuring the stress on the wafer after forming the at least one semiconductor device structure over the first surface of the substrate and before subjecting the at least one material to the at least one chemical-mechanical polishing process.

19. A method of alleviating adverse effects of stress on a wafer comprising forming recesses in a surface of the wafer to produce at least one stress on the wafer of at least one of a type, a direction, and a magnitude of opposite type than that of at least one other stress imposed on the wafer resulting from the formation of a semiconductor device structure over another surface of the wafer.

20. The method of claim 19, wherein transitions between the recesses and elevated regions adjacent to the recesses are substantially smooth and continuous.
